(19) United States
(12) Patent Application Publication
(10) Pub. No.: US 2002/0114886 A1
(43) Pub. Date: Aug. 22, 2002

(54) Method of tisin deposition using a chemical vapor deposition process

(75) Inventors: Jing-Pei Chou, Sunnyvale, CA (US); Chien-Teh Kao, Sunnyvale, CA (US); Chiukin Steven Lai, Sunnyvale, CA (US); Roderick Craig Mosely, Pleasanton, CA (US); Mei Chang, Saratoga, CA (US); Fufa Chen, Cupertino, CA (US)

Correspondence Address: Patent Counsel, Applied Materials, Inc., 3050 Bowers Avenue, P.O. Box 450A, Santa Clara, CA, 95052, US

(73) Assignee: APPLIED MATERIALS, INC.

(21) Appl. No.: 10/026,378

(22) Filed: Dec. 21, 2001

Related U.S. Application Data
(63) Continuation-in-part of application No. 08/808,246, filed on Feb. 28, 1997.
(63) Continuation-in-part of application No. 08/498,990, filed on Jul. 6, 1995, now abandoned.
(63) Continuation-in-part of application No. 08/567,461, filed on Dec. 5, 1995, now abandoned.
(63) Continuation-in-part of application No. 08/677,185, filed on Jul. 9, 1996, now Pat. No. 6,155,198.
(63) Continuation-in-part of application No. 08/677,218, filed on Jul. 9, 1996, now abandoned.
(63) Continuation-in-part of application No. 08/680,913, filed on Jul. 12, 1996, now abandoned.

(51) Int. Cl. C23C 16/14

(52) U.S. Cl. 427/255.391; 427/569

(57) ABSTRACT

A method of forming a titanium silicide nitride (TiSiN) layer is described. A titanium nitride (TiN) layer is deposited on a substrate, the process chamber is purged to remove reaction by-products therefrom and than the titanium nitride (TiN) layer is exposed to a silicon-containing gas to form the titanium suicide nitride (TiSiN) layer. Alternatively, the substrate may be exposed to the silicon-containing gas in a process chamber different from the one used for the titanium nitride (TiN) layer deposition.

### CROSS-REFERENCE TO RELATED APPLICATIONS

This application is a continuation-in-part of the following U.S. patent applications:

U.S. patent application No. 08/808,246, entitled “METHOD FOR CONSTRUCTING A FILM ON A SEMICONDUCTOR WAFER” and filed on Feb. 28, 1997;

U.S. patent application No. 08/498,990, entitled “BIASED PLASMA ANNEALING OF THIN FILMS” and filed on Jul. 6, 1995;

U.S. patent application No. 08/567,461, entitled “PLASMA ANNEALING OF THIN FILMS” and filed on Dec. 5, 1995;

U.S. patent application No. 08/677,185, entitled “CHAMBER FOR CONSTRUCTING AN OXIDIZED FILM ON A SEMICONDUCTOR WAFER” and filed on Jul. 9, 1996;

U.S. patent application No. 08,677,218, entitled “IN-SITU CONSTRUCTION OF AN OXIDIZED FILM ON A SEMICONDUCTOR WAFER” and filed on Jul. 9, 1996; and

U.S. patent application No. 08/680,913, entitled “PLASMA BOMBARDING OF THIN FILMS” and filed on Jul. 12, 1996.

Each of the aforementioned related patent applications are hereby incorporated by reference.

### BACKGROUND OF THE INVENTION

1. Field of the Invention

The present invention relates to titanium suicide nitride (TiSiN) layers and, more particularly, to a method of forming titanium silicide nitride (TiSiN) layers.

2. Description of the Related Art

In the manufacture of integrated circuits, intermediate or transition layers are often used as metal barrier layers to inhibit the diffusion of metals into an underlying region beneath the barrier layer and/or to enhance adhesion of subsequently formed layers. These underlying regions include transistor gates, capacitor dielectric, semiconductor substrates, metal lines, and many other structures that appear in integrated circuits.

For example, when a transistor gate electrode is formed, a diffusion barrier is typically formed between the gate material (e.g., polysilicon (Si)) and the metal (e.g., tungsten (W), copper (Cu), aluminum (Al)) comprising the electrode. The diffusion barrier inhibits metal diffusion into the gate material. Such metal diffusion is undesirable because it would change the characteristics of the transistor, or render it inoperative. A combination of titanium/titanium silicide nitride (TiSiN), for example, is often used as a diffusion barrier.

Such diffusion barrier material may also be used in a tungsten (W) metallization process to provide contacts to source and drain regions of a transistor. For example, in a tungsten (W) plug process, a titanium (Ti) layer is deposited on a silicon (Si) substrate. A titanium silicide nitride (TiSIN) layer is then formed upon the titanium (Ti) layer, prior to forming the tungsten (W) plug. In addition to being a barrier material, the titanium silicide nitride (TiSiN) layer serves two additional functions: 1) prevents chemical attack of the titanium (Ti) by tungsten hexafluoride (WF₆) during tungsten (W) deposition; and 2) acts as a glue layer to promote adhesion of the tungsten (W) plug.

The titanium silicide nitride (TiSiN) layer may be formed using a chemical vapor deposition process. For example, titanium tetrachloride (TiCl₄), ammonia (NH₃), and silane (SiH₄) may be thermally reacted to form titanium suicide nitride (TiSiN). Alternatively, titanium tetrachloride (TiCl₄) and ammonia (NH₃) may be thermally reacted to form a titanium nitride (TiN) layer, into which silicon (Si) is subsequently incorporated by treating such layer using a silicon-containing gas (e.g., silane (SiH₄)).

However, when a TiCl₄-based chemistry is used to form the titanium silicide nitride (TiSiN) layer, reliability problems are encountered. In particular, by-products generated during the titanium nitride (TiN) layer formation may react with the silicon-containing gas inhibiting the incorporation of silicon (Si) therein, and adversely affecting the adhesion/barrier properties of the titanium suicide nitride (TiSiN) layer.

Therefore, there is a need in the art for a method of forming titanium suicide nitride (TiSiN) layers having improved film characteristics.

### SUMMARY OF THE INVENTION

The present invention relates to a method of forming a titanium silicide nitride (TiSiN) layer. The titanium suicide nitride (TiSiN) layer is formed by depositing a titanium nitride (TiN) layer on a substrate in a process chamber. After the titanium nitride (TiN) layer is deposited on the substrate, reaction by-products generated during titanium nitride (TiN) layer formation are removed from the process chamber. The reaction by-products are removed by first providing a purge gas to the process chamber and than evacuating both the purge gas as well as the reaction by-products therefrom. After the reaction by-products are removed from the process chamber, the titanium nitride (TiN) layer is exposed to a silicon-containing gas. The titanium nitride (TiN) layer reacts with the silicon-containing gas to form the titanium silicide nitride (TiSiN) layer. Alternatively, the substrate may be exposed to the silicon-containing gas in a separate process chamber different from the one used for the titanium nitride (TiN) layer deposition, in order to prevent a reaction between the silicon-containing gas and reaction by-products generated during the titanium nitride (TiN) layer formation.

The formation of the titanium silicide nitride (TiSiN) layer is compatible with integrated circuit fabrication processes. In one integrated circuit fabrication process, the titanium silicide nitride (TiSiN) layer is used as a diffusion barrier for a tungsten (W) metallization process. For such an embodiment, a preferred process sequence includes depositing a titanium nitride (TiN) layer in apertures defined in a dielectric material layer formed on a silicon substrate, such that the titanium nitride (TiN) layer contacts the silicon substrate. After the titanium nitride (TiN) layer is deposited on the substrate, reaction by-products generated during titanium nitride (TiN) layer formation are removed from the process chamber. The reaction by-products are removed by first providing a purge gas to the process chamber and than evacuating both the purge gas as well as the reaction by-products therefrom. After the reaction by-products are removed from the process chamber, the titanium nitride (TiN) layer is exposed to a silicon-containing gas. The titanium nitride (TiN) layer reacts with the silicon-containing gas to form the titanium silicide nitride (TiSiN) layer. Thereafter, the tungsten metallization process is completed when the apertures are filled with tungsten (W).

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 depicts a schematic illustration of an apparatus that can be used for the practice of embodiments described herein;

FIG. 2 depicts a schematic cross-sectional view of a chemical vapor deposition (CVD) chamber;

FIG. 3 illustrates a process sequence incorporating titanium suicide nitride (TiSiN) formation steps according to one embodiment described herein;

FIGS. 4A-4C illustrate process sequences incorporating titanium silicide nitride (TiSiN) formation steps according to alternate embodiments described herein; and

FIGS. 5A-5D depict schematic cross-sectional views of a substrate structure at different stages of an integrated circuit fabrication sequence incorporating a titanium silicide nitride (TiSiN) layer formed according to an embodiment described herein.

### DETAILED DESCRIPTION OF THE PREFERRED EMBODIMENT

Wafer Processing System

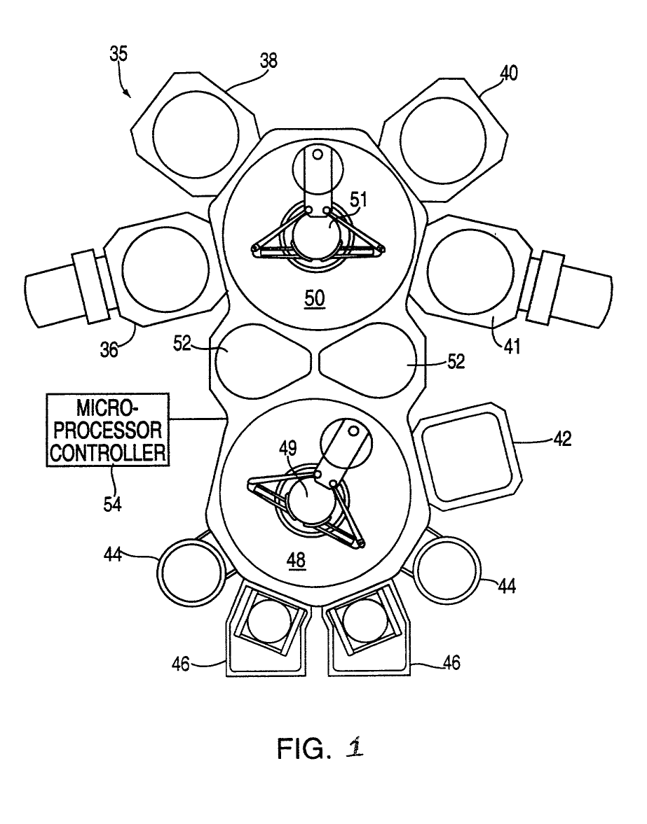

FIG. 1 is a schematic representation of a wafer processing system 35 that can be used to perform integrated circuit fabrication in accordance with embodiments described herein. The wafer processing system 35 typically comprises process chambers 36, 38, 40, 41, degas chambers 44, load-lock chambers 46, transfer chambers 48, 50, pass-through chambers 52, a microprocessor controller 54, along with other hardware components such as power supplies (not shown) and vacuum pumps (not shown). An example of such a wafer processing system 35 is an ENDURA® System, commercially available from Applied Materials, Inc., Santa Clara, Calif.

Details of the wafer processing system 35 are described in commonly assigned U.S. Pat. No. 5,186,718, entitled “Staged-Vacuum Substrate Processing System and Method”, issued Feb. 16, 1993, and is hereby incorporated by reference. The salient features of the wafer processing system 35 are briefly described below.

The wafer processing system 35 includes two transfer chambers 48, 50, each containing a transfer robot 49, 51. The transfer chambers 48, 50 are separated one from the other by pass-through chambers 52.

Transfer chamber 48 is coupled to load-lock chambers 46, degas chambers 44, pre-clean chamber 42 and pass-through chambers 52. Substrates (not shown) are loaded into the wafer processing system 35 through load-lock chambers 46. Thereafter, the substrates are sequentially degassed and cleaned in degas chambers 44 and the pre-clean chamber 42, respectively. The transfer robot 48 moves the substrates between the degas chambers 44 and the pre-clean chamber 42.

Transfer chamber 50 is coupled to a cluster of process chambers 36, 38, 40, 41. The cleaned substrates are moved from transfer chamber 48 into transfer chamber 50 via pass-through chambers 52. Thereafter, transfer robot 51 moves the substrates between one or more of the process chambers 36, 38, 40, 41.

The process chambers 36, 38, 40, 41 are used to perform various integrated circuit fabrication sequences. For example, process chambers 36, 38, 40, 41 may include chemical vapor deposition (CVD) chambers, physical vapor deposition (PVD) chambers, ionized metal plasma physical vapor deposition (IMP PVD) chambers, rapid thermal process (RTP) chambers and plasma etch (PE) chambers, among others.

Chemical Vapor Deposition (CVD) Process Chamber

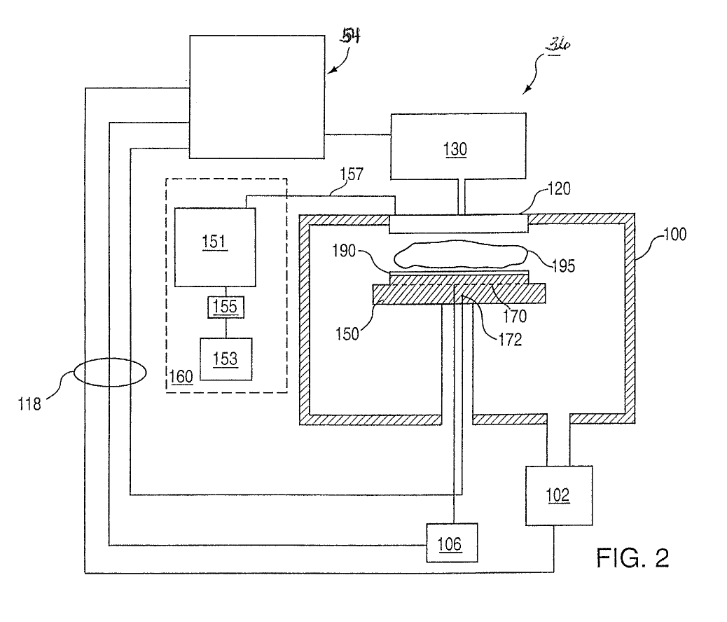

FIG. 2 depicts a schematic cross-sectional view of a chemical vapor deposition (CVD) process chamber 36 of wafer processing system 35. CVD process chamber 36 may be used to deposit metal-containing barrier layers on semiconductor wafers. An example of such a CVD process chamber 36 include TxZ® chambers, commercially available from Applied Materials, Inc., Santa Clara, Calif.

The CVD process chamber 36 generally houses a wafer support pedestal 150, which is used to support a substrate 190. The wafer support pedestal 150 can typically be moved in a vertical direction inside the CVD process chamber 36 using a displacement mechanism (not shown).

Depending on the specific CVD process, the substrate 190 can be heated to some desired temperature prior to or during deposition. For example, the wafer support pedestal 150 may be heated by an embedded heater element 170. The wafer support pedestal 150 may be resistively heated by applying an electric current from an AC power supply 106 to the heater element 170. The substrate 190 is, in turn, heated by the pedestal 150.

A temperature sensor 172, such as a thermocouple, is also embedded in the wafer support pedestal 150 to monitor the temperature of the pedestal 150 in a conventional manner. The measured temperature is used in a feedback loop to control the AC power supply 106 for the heating element 170, such that the substrate temperature can be maintained or controlled at a desired temperature which is suitable for the particular process application.

A vacuum pump 102 is used to evacuate the CVD process chamber 36 and to maintain the proper gas flows and pressures inside such chamber 36. A showerhead 120, through which process gases are introduced into the process chamber 36, is located above the wafer support pedestal 150. The showerhead 120 is connected to a gas panel 130, that controls and supplies various gases provided to the process chamber 36.

Proper control and regulation of the gas flows through the gas panel 130 is performed by mass flow controllers (not shown) and a microprocessor controller 54 (FIG. 1). The showerhead 120 allows process gases from the gas panel 130 to be uniformly introduced and distributed in the CVD process chamber 36.

The CVD process chamber 36 may comprise additional components for enhancing layer deposition on the substrate 190. For example, the showerhead 120 and the wafer support pedestal 150 may also form a pair of spaced apart electrodes. When an electric field is generated between these electrodes, the process gases introduced into the chamber 36 are ignited into a plasma.

Typically, the electric field is generated by coupling the wafer support pedestal 150 to a source of radio frequency (RF) power (not shown) through a matching network (not shown). Alternatively, the RF power source and matching network may be coupled to the showerhead 120, or coupled to both the showerhead 120 and the wafer support pedestal 150.

Plasma enhanced chemical vapor deposition (PECVD) techniques promote excitation and/or disassociation of the reactant gases by the application of the electric field to the reaction zone near the substrate surface, creating a plasma of reactive species. The reactivity of the species in the plasma reduces the energy required for a chemical reaction to take place, in effect lowering the required temperature for such PECVD processes.

Optionally, a remote plasma source 160 may be coupled to the CVD process chamber 36, to provide a remotely generated plasma to the process chamber 36. The remote plasma source 160 includes a gas supply 153, a gas flow controller 155, a plasma chamber 151, and a chamber inlet 157. The gas flow controller 155 controls the flow of process gas from the gas supply 153 to the plasma chamber 151.

A remote plasma may be generated by applying an electric field to the process gas in the plasma chamber 151, creating a plasma of reactive species. Typically, the electric field is generated in the plasma chamber 151 using an RF source (not shown). The reactive species generated in the remote plasma source 150 are introduced into the process chamber 36 through inlet 157.

The CVD process chamber 36 is controlled by a microprocessor controller 54. The microprocessor controller 54 may be one of any form of general purpose computer processor (CPU) that can be used in an industrial setting for controlling various chambers and sub-processors. The computer processor may use any suitable memory, such as random access memory, read only memory, floppy disk drive, hard disk, or any other form of digital storage, local or remote. Various support circuits may be coupled to the CPU for supporting the processor in a conventional manner. Software routines as required may be stored in the memory or executed by a second CPU that is remotely located.

The software routines are executed after the substrate is positioned on the pedestal. The software routines, when executed, transform the general purpose computer into a specific process computer that controls the chamber operation so that a chamber process is performed. Alternatively, the software routines may be performed in hardware, as an application specific integrated circuit or other type of hardware implementation, or a combination of software and hardware.

Titanium Silicide Nitride Layer Formation Process

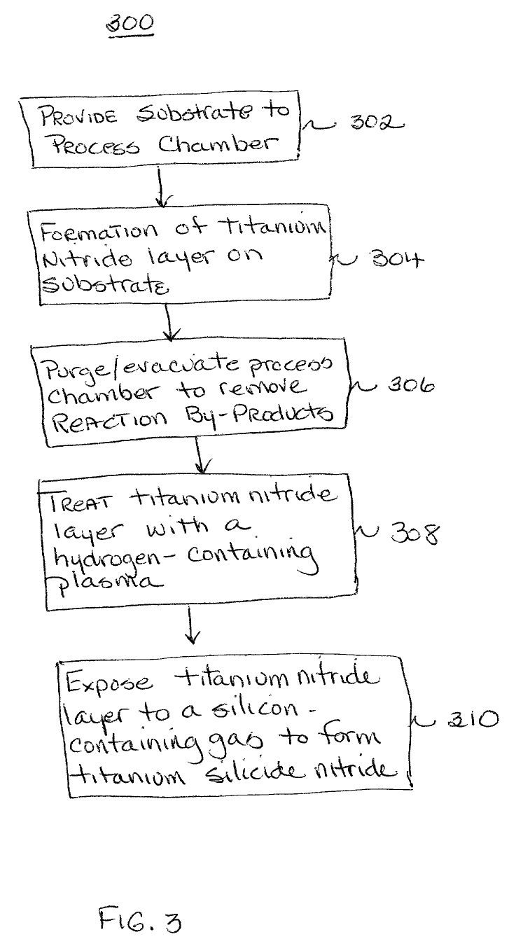

FIG. 3 illustrates a process sequence 300 detailing the various steps used for the formation of a titanium silicide nitride (TiSiN) layer. These steps may be performed in a single CVD process chamber similar to that describe above with reference to FIG. 2. As shown in step 302, a substrate is provided to the CVD process chamber. The substrate may be, for example, a silicon substrate, which may or may not have one or more material layers disposed thereon. Such one or more material layers, for example, may be an oxide layer having a contact hole therein that exposes the surface of the silicon substrate.

In step 304, a titanium nitride (TiN) layer is deposited on the substrate in contact with the silicon surface. The titanium nitride (TiN) layer may be formed, for example, from a reaction of titanium tetrachloride (TiCl₄) and ammonia (NH₃). In one embodiment, titanium tetrachloride (TiCl₄), helium (He) and nitrogen (N₂) are introduced into the CVD deposition chamber via a first pathway (gas line) of the showerhead 120. Ammonia (NH₃), along with nitrogen (N₂), is introduced into the deposition chamber via a second pathway of the showerhead. Helium (He) and argon (Ar), or other inert gases, may also be used, either singly or in combination (i.e., as a gas mixture) within either gas line of the showerhead 120.

Typically, the reaction can be performed at a titanium tetrachloride (TiCl₄) flow rate of about 50 mg/min (milligrams/minute) to about 350 mg/min introduced into the deposition chamber through the first pathway of the showerhead and an ammonia (NH₃) flow rate of about 100 sccm (standard cubic centimeters per minute) to about 500 sccm introduced into the deposition chamber through the second pathway of the showerhead. A total pressure range of about 5 torr to about 30 torr and a pedestal temperature between about 400° C. to about 700° C. may be used. The above deposition parameters provide a deposition rate for titanium nitride (TiN) of about 5 Å/sec (Angstoms/second) to about 13 Å/sec.

More preferably the titanium nitride (TiN) layer is deposited at a titanium tetrachloride (TiCl₄) flow rate of about 170 mg/min in about 1000 sccm of helium (He) and about 1000 sccm of nitrogen (N₂), along with an ammonia (NH₃) flow rate of about 100 sccm in about 2000 sccm of nitrogen (N₂), at a total pressure of about 10 torr and a temperature of about 680° C. Under these process conditions, the titanium nitride (TiN) layer exhibits a step coverage of at least 95% for an aspect ratio of about 4:1 to about 8:1 (aspect ratio is define as the ratio of the depth of a feature to the width of the feature).

Referring to step 306, after the titanium nitride (TiN) layer is deposited on the substrate, the process chamber is purged to remove any reaction by-products generated during titanium nitride (TiN) layer formation. These undesirable reaction by-products may interfere with the adhesion properties of films subsequently deposited on the titanium silicide nitride (TiSiN) layer, such as for example, a tungsten (W) layer. The process chamber is purged by providing a purge gas to the process chamber and then evacuating both the purge gas as well as the reaction by-products therefrom.

The purge gas may be one or more gases selected from the group of nitrogen (N₂), hydrogen (H₂), helium (He), argon (Ar), neon (Ne) and xenon (Xe), among others. Typically, the process chamber is purged by providing thereto a purge gas at a flow rate of about 100 sccm to about 1000 sccm, for up to about 5 minutes.

In step 308, after the process chamber is purged to remove any reaction by-products generated during titanium nitride (TiN) layer formation, the titanium nitride (TiN) layer is treated using a hydrogen-containing plasma. The hydrogen-containing plasma may be generated from a gas mixture comprising one or more gases selected from the group consisting of hydrogen (H₂), ammonia (NH₃) and hydrazine (N₂H₄), among others. Dilutant gases such as nitrogen (N₂), argon (Ar) and helium (He), among others may also be added to the gas mixture.

Typically, the titanium nitride (TiN) layer is plasma treated at a substrate temperature of about 400° C. to about 700° C., a chamber pressure of about 5 torr to about 30 torr, a hydrogen-containing gas flow rate of about 100 sccm to about 1000 sccm, a radio frequency (RF) power of about 0.5 W/cm² (Watts/centimeter ) to about 10 W/cm², and a plate spacing of about 300 mils to about 500 mils. The titanium nitride (TiN) layer is plasma treated for about 5 seconds to about 100 seconds, depending on the layer thickness. When the hydrogen-containing plasma also includes nitrogen a nitrogen/hydrogen gas flow ratio of about 0.1 to about 1 is preferred.

Referring to step 310, the plasma treated titanium nitride (TiN) layer is exposed to a silicon-containing gas for silicon (Si) incorporation into the layer of titanium nitride (TiN), converting it into a titanium silicide nitride (TiSiN) layer. The silicon-containing gas may be, for example, silane (SiH₄) or disilane (Si₂H₆), among others. The silicon-containing gas may be mixed with one or more gases selected from the group consisting of hydrogen (H₂), nitrogen (N₂), argon (Ar) and helium (He), among others.

Typically, the silicide formation step can be performed with a silicon-containing gas flow rate of about 20 sccm to about 3000 sccm, a total pressure of about 0.5 torr to about 20 torr and a temperature of about 500° C. to about 700° C. When the silicon-containing gas is mixed with hydrogen (H₂), the ratio of the silicon-containing gas to the hydrogen (H₂) is preferably greater than 1. More preferably the silicide formation step is performed with a silicon-containing gas flow rate of about 80 sccm, a hydrogen (H₂) flow rate of about 450 sccm, a total pressure of about 5 torr and a temperature of about 650° C.

Other process chambers are within the scope of the invention, and the parameters listed above may vary according to the particular process chamber used to form the titanium silicide nitride (TiSiN) layer. For example, other process chambers may have a larger (e.g., configured to accommodate 300 millimeter substrates) or smaller volume, requiring gas flow rates that are larger or smaller than those recited for process chambers available from Applied Materials, Inc., Santa Clara, Calif.

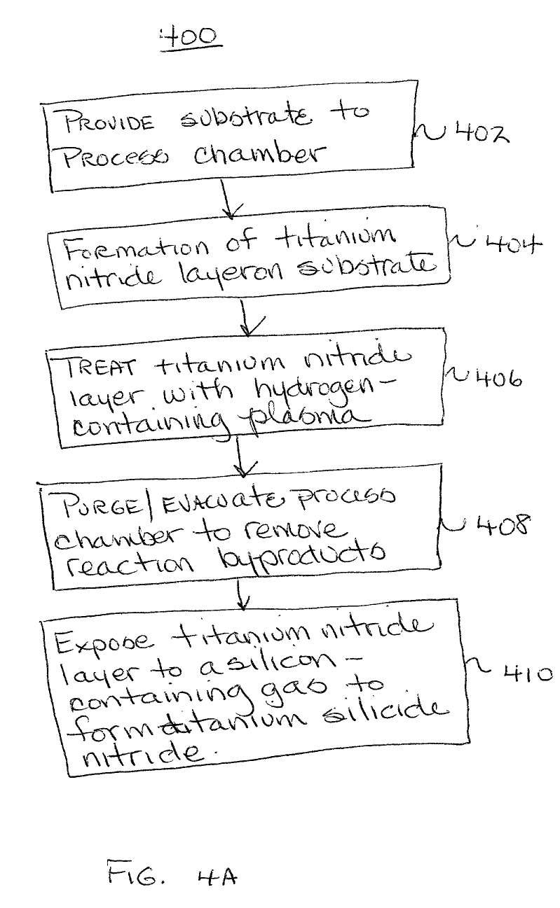

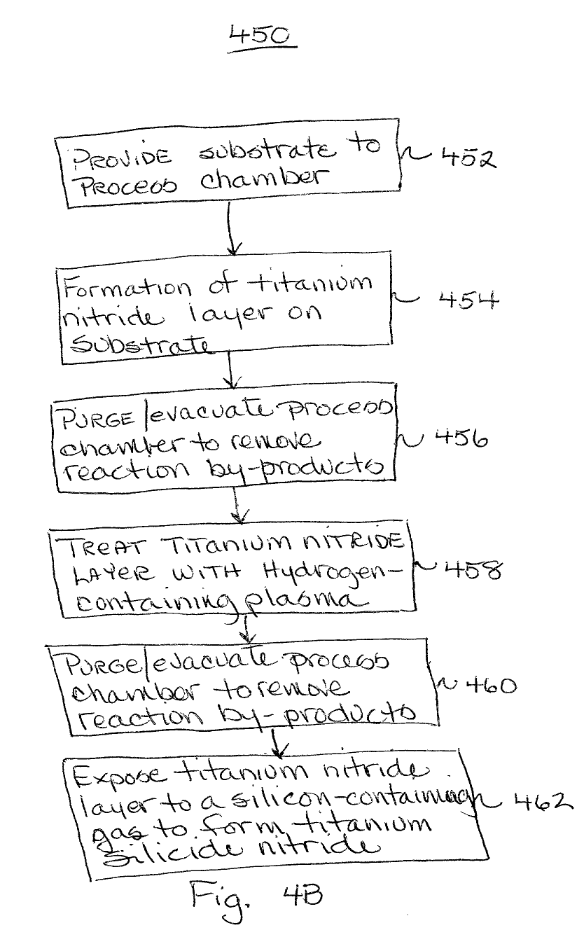

In the fabrication sequence described with respect to FIG. 3, the purge step 306 is performed after titanium nitride (TiN) layer deposition 304 and prior to the hydrogen-containing plasma treatment step 308. Alternatively, referring to FIG. 4A, the purge step may be performed after the hydrogen-containing plasma treatment step and prior to the silicide formation step. For such an embodiment, a titanium silicide nitride fabrication sequence 400 includes providing a substrate to the process chamber (step 402), depositing a titanium nitride (TiN) layer on the substrate (step 404), treating the titanium nitride (TiN) layer with a hydrogen-containing plasma (step 406), purging the process chamber to remove any reaction by-products generated during titanium nitride (TiN) layer formation (step 408) and exposing the titanium nitride (TiN) layer to a silicon-containing gas to convert it to a titanium silicide nitride (TiSiN) layer (step 410).

In another embodiment, more than one purge step may be performed. Referring to FIG. 4B, a first purge step may be performed after titanium nitride (TiN) layer deposition and a second purge step may be performed after the hydrogen-containing plasma treatment step. For such an embodiment, a titanium silicide nitride fabrication sequence 450 includes providing a substrate to the process chamber (step 452), depositing a titanium nitride (TiN) layer on the substrate (step 454), purging the process chamber to remove any reaction by-products generated during titanium nitride (TiN) layer formation (step 456), treating the titanium nitride (TiN) layer with a hydrogen-containing plasma (step 458), purging the process chamber to remove any reaction by-products generated during the titanium nitride (TiN) layer formation (step 460) and exposing the titanium nitride (TiN) layer to a silicon-containing gas to convert it to a titanium silicide nitride (TiSiN) layer (step 462).

In yet another embodiment, two different process chambers are utilized to form the titanium silicide nitride (TiSiN) layer. For such an embodiment, a titanium silicide nitride fabrication sequence 500 includes providing a substrate to a first process chamber (step 502), depositing a titanium nitride (TiN) layer on the substrate (step 504), treating the titanium nitride (TiN) with a hydrogen-containing plasma (step 506), placing the substrate in a second process chamber to remove any reaction by-products generated during the titanium nitride (TiN) layer formation (step 508) and exposing the titanium nitride (TiN) layer to a silicon-containing gas to convert it to a titanium silicide nitride (TiSiN) layer (step 510).

Integrated Circuit Fabrication Process

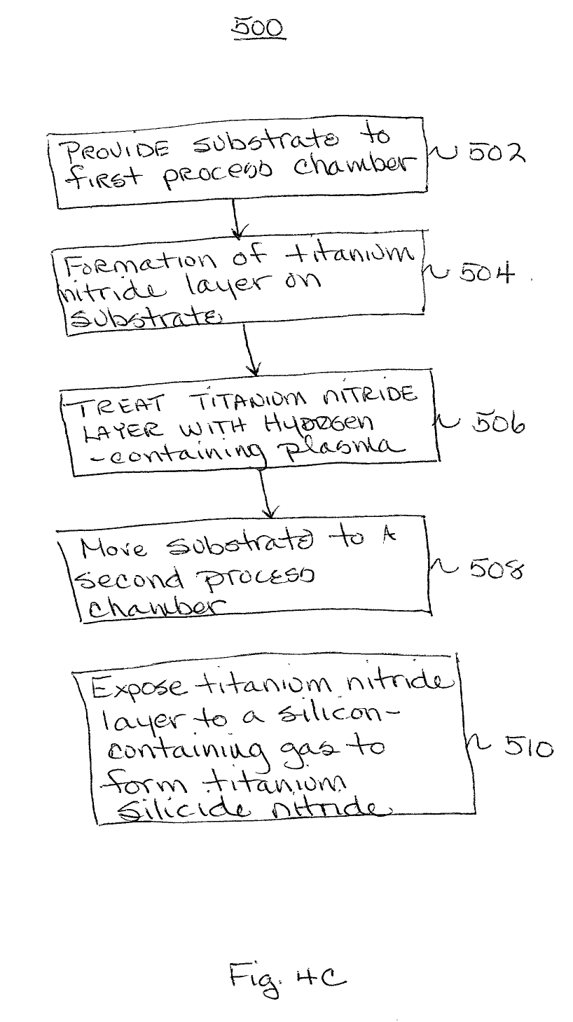

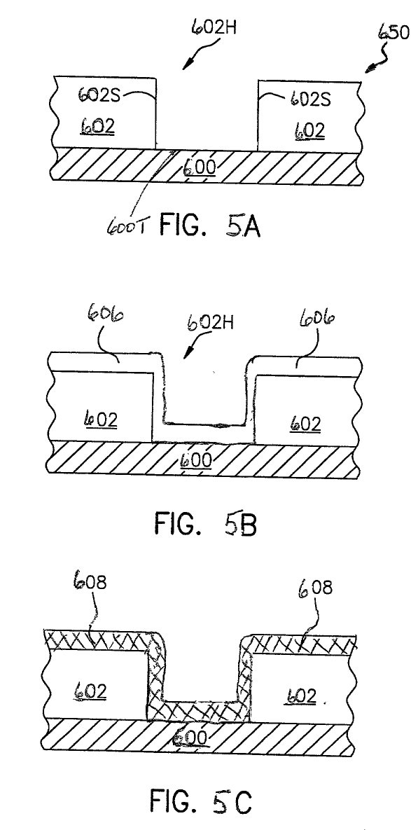

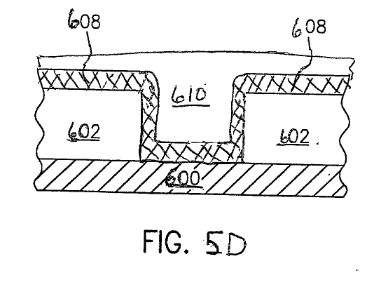

FIGS. 5A-5D illustrate schematic cross-sectional views of a substrate 600 at different stages of a tungsten plug fabrication sequence incorporating a titanium silicide nitride (TiSiN) layer formed according to an embodiment described herein. In general, the substrate 600 refers to any workpiece upon which film processing is performed, and a substrate structure 650 is used to generally denote the substrate 600 as well as other material layers formed on the substrate 600. Depending on the specific stage of processing, the substrate 600 may be a silicon semiconductor wafer, or other material layer, which has been formed thereon. FIG. 5A, for example, shows a cross-sectional view of a substrate structure 650, having a material layer 602 thereon. In this particular illustration, the material layer 602 may be an oxide (e.g., silicon dioxide). The material layer has been conventionally formed and patterned to provide a contact hole 602H extending to the top surface 600T of the substrate 600.

A titanium nitride (TiN) layer 606 is deposited in the contact hole 602H, as illustrated in FIG. 5B. The titanium nitride layer 606 is formed according to the process parameters described above with respect to step 306 of FIG. 3. The thickness of the titanium nitride (TiN) layer 606 is variable depending on the specific stage of processing. Typically, the titanium nitride (TiN) layer 606 has a thickness of about 20 Å to about 500 Å.

After the titanium nitride layer 606 is formed, the process chamber is purged and the titanium nitride layer 606 is treated with the hydrogen-containing plasma, as described above with respect to step 308 (FIG. 3) and step 310 (FIG. 3), respectively. Thereafter, the titanium nitride (TiN) layer 606 is exposed to a silicon-containing gas to convert it to a titanium silicide nitride (TiSIN) layer 608 as described above with reference to step 312 (FIG. 3) and illustrated in FIG. 5C.

Referring to FIG. 5D, the plug fabrication sequence is completed by filling the contact holes 602H with tungsten (W) 610. The tungsten (W) may be deposited on the titanium silicide nitride (TiSiN) layer 608, for example, by reacting tungsten hexafluoride (WF₆) and hydrogen (H₂). Adhesion of the tungsten (W) is improved by the presence of the titanium silicide nitride (TiSiN) layer 608 formed using the embodiments described herein.

While foregoing is directed to the preferred embodiment of the present invention, other and further embodiments of the invention may be devised without departing from the basic scope thereof, and the scope thereof is determined by the claims that follow.

What is claimed is:

1. A method of film deposition, comprising:
forming a titanium nitride (TiN) layer on a substrate in a process chamber;
removing reaction by-products generated during titanium nitride (TiN) layer formation from the process chamber; and
exposing the titanium nitride (TiN) layer to a silicon-containing gas to convert the titanium nitride (TiN) layer to a titanium silicide nitride (TiSiN) layer.

2. The method of claim 1 wherein the reaction by-products are removed from the process chamber by providing a purge gas thereto and evacuating both the purge gas and the reaction by-products therefrom.

3. The method of claim 2 wherein the purge gas comprises one or more gases selected from the group consisting of nitrogen (N₂), hydrogen (H₂), helium (He), argon (Ar), neon (Ne) and xenon (Xe).

4. The method of claim 2 wherein the purge gas is provided to the process chamber for up to about 5 minutes.

5. The method of claim 1 wherein the titanium nitride (TiN) layer is formed from a reaction of titanium tetrachloride (TiCl₄) and ammonia (NH₃).

6. The method of claim 1 wherein the silicon-containing gas is selected from the group consisting of silane (SiH₄) and disilane (Si₂H₆).

7. The method of claim 6 wherein the silicon-containing gas is mixed with one or more gases selected from the group consisting of hydrogen (H₂), nitrogen (N₂), argon (Ar) and helium (He).

8. The method of claim 7 wherein the silicon-containing gas is mixed with hydrogen (H₂).

9. The method of claim 8 wherein the ratio of the silicon-containing gas to the hydrogen (H₂) is greater than 1.

10. The method of claim 1 further comprising treating the titanium nitride (TiN) layer with a hydrogen-containing plasma prior to exposing the titanium nitride (TiN) layer to the silicon-containing gas.

11. The method of claim 10 wherein the titanium nitride (TiN) layer is treated after reaction by-products generated during titanium nitride (TiN) layer formation are removed from the process chamber.

12. The method of claim 10 wherein the titanium nitride (TiN) layer is treated before reaction by-products generated during titanium nitride (TiN) layer formation are removed from the process chamber.

13. The method of claim 10 wherein the hydrogen-containing plasma is generated by applying an electric field to a gas mixture comprising one or more gases selected from the group consisting of hydrogen (H₂), ammonia (NH₃), hydrazine (N₂H₄), nitrogen (N₂), argon (Ar) and helium (He).

14. The method of claim 10 wherein the titanium nitride (TiN) layer is treated with the hydrogen-containing plasma for about 5 seconds to about 100 seconds.

15. A method of film deposition, comprising:
(a) forming a titanium nitride (TiN) layer on a substrate in a process chamber;
(b) removing reaction by-products generated during titanium nitride (TiN) layer formation from the process chamber;
(c) treating the titanium nitride (TiN) layer with a hydrogen-containing plasma;
(d) removing reaction by-products generated during titanium nitride (TiN) layer formation from the process chamber; and
(e) exposing the titanium nitride (TiN) layer to a silicon-containing gas to convert the titanium nitride (TiN) layer to a titanium silicide nitride (TiSiN) layer.

16. The method of claim 15 wherein the reaction by-products are removed from the process chamber in steps (b) and (d) by providing a purge gas thereto and evacuating both the purge gas and the reaction by-products therefrom.

17. The method of claim 16 wherein the purge gas comprises one or more gases selected from the group consisting of nitrogen (N₂), hydrogen (H₂), helium (He), argon (Ar), neon (Ne) and xenon (Xe).

18. The method of claim 16 wherein the purge gas is provided to the process chamber for up to about 5 minutes.

19. The method of claim 15 wherein the titanium nitride (TiN) layer is formed from a reaction of titanium tetrachloride (TiCl₄) and ammonia (NH₃).

20. The method of claim 15 wherein the silicon-containing gas is selected from the group consisting of silane (SiH₄) and disilane (Si₂H₆).

21. The method of claim 20 wherein the silicon-containing gas is mixed with one or more gases selected from the group consisting of hydrogen (H₂), nitrogen (N₂), argon (Ar) and helium (He).

22. The method of claim 21 wherein the silicon-containing gas is mixed with hydrogen (H₂).

23. The method of claim 22 wherein the ratio of the silicon-containing gas to the hydrogen (H₂) is greater than 1.

24. The method of claim 15 wherein the hydrogen-containing plasma is generated by applying an electric field to a gas mixture comprising one or more gases selected from the group consisting of hydrogen (H₂), ammonia (NH₃), hydrazine (N₂H₄), nitrogen (N₂), argon (Ar) and helium (He).

25. The method of claim 15 wherein the titanium nitride (TiN) layer is treated with the hydrogen-containing plasma for about 5 seconds to about 100 seconds.

26. A method of forming a barrier layer for use in integrated circuit fabrication, comprising:
forming a titanium nitride (TiN) layer on a substrate in a process chamber;
removing reaction by-products generated during titanium nitride (TiN) layer formation from the process chamber;
exposing the titanium nitride (TiN) layer to a silicon-containing gas to convert the titanium nitride (TiN) layer to a titanium silicide nitride (TiSiN) layer; and
forming a metal layer on the titanium silicide nitride (TiSiN) layer.

27. The method of claim 26 wherein the reaction by-products are removed from the process chamber by providing a purge gas thereto and evacuating both the purge gas and the reaction by-products therefrom.

28. The method of claim 27 wherein the purge gas comprises one or more gases selected from the group consisting of nitrogen (N₂), hydrogen (H₂), helium (He), argon (Ar), neon (Ne) and xenon (Xe).

29. The method of claim 27 wherein the purge gas is provided to the process chamber for up to about 5 minutes.

30. The method of claim 26 wherein the titanium nitride (TiN) layer is formed from a reaction of titanium tetrachloride (TiCl₄) and ammonia (NH₃).

31. The method of claim 26 wherein the silicon-containing gas is selected from the group consisting of silane (SiH₄) and disilane (Si₂H₆).

32. The method of claim 31 wherein the silicon-containing gas is mixed with one or more gases selected from the group consisting of hydrogen (H₂), nitrogen (N₂), argon (Ar) and helium (He).

33. The method of claim 32 wherein the silicon-containing gas is mixed with hydrogen (H₂).

34. The method of claim 33 wherein the ratio of the silicon-containing gas to the hydrogen (H₂) is greater than 1.

35. The method of claim 26 further comprising treating the titanium nitride (TiN) layer with a hydrogen-containing plasma prior to exposing the titanium nitride (TiN) layer to the silicon-containing gas.

36. The method of claim 35 wherein the titanium nitride (TiN) layer is treated after reaction by-products generated during titanium nitride (TiN) layer formation are removed from the process chamber.

37. The method of claim 35 wherein the titanium nitride (TiN) layer is treated before reaction by-products generated during titanium nitride (TiN) layer formation are removed from the process chamber.

38. The method of claim 35 wherein the hydrogen-containing plasma is generated by applying an electric field to a gas mixture comprising one or more gases selected from the group consisting of hydrogen (H₂), ammonia (NH₃), hydrazine (N₂H₄), nitrogen (N₂), argon (Ar) and helium (He).

39. The method of claim 35 wherein the titanium nitride (TiN) layer is treated with the hydrogen-containing plasma for about 5 seconds to about 100 seconds.

40. A method of film deposition, comprising:
forming a titanium nitride (TiN) layer on a substrate in a first process chamber;
moving the substrate with the titanium nitride (TiN) layer thereon into a second process chamber different from the first process chamber; and
exposing the titanium nitride (TiN) layer to a silicon-containing gas to convert the titanium nitride (TiN) layer to a titanium silicide nitride (TiSiN) layer.

41. The method of claim 40 wherein the titanium nitride (TiN) layer is formed from a reaction of titanium tetrachloride (TiCl₄) and ammonia (NH₃).

42. The method of claim 40 wherein the silicon-containing gas is selected from the group consisting of silane (SiH₄) and disilane (Si₂H₆).

43. The method of claim 42 wherein the silicon-containing gas is mixed with one or more gases selected from the group consisting of hydrogen (H₂), nitrogen (N₂), argon (Ar) and helium (He).

44. The method of claim 43 wherein the silicon-containing gas is mixed with hydrogen (H₂).

45. The method of claim 44 wherein the ratio of the silicon-containing gas to the hydrogen (H₂) is greater than 1.

46. The method of claim 40 further comprising treating the titanium nitride (TiN) layer with a hydrogen-containing plasma prior to exposing the titanium nitride (TiN) layer to the silicon-containing gas.

47. The method of claim 46 wherein the titanium nitride (TiN) layer is treated after moving the substrate into the second process chamber.

48. The method of claim 46 wherein the titanium nitride (TiN) layer is treated before moving the substrate into the second process chamber.

49. The method of claim 46 wherein the hydrogen-containing plasma is generated by applying an electric field to a gas mixture comprising one or more gases selected from the group consisting of hydrogen (H₂), ammonia (NH₃), hydrazine (N₂H₄), nitrogen (N₂), argon (Ar) and helium (He).

50. The method of claim 46 wherein the titanium nitride (TiN) layer is treated with the hydrogen-containing plasma for about 5 seconds to about 100 seconds.

51. A method of film deposition, comprising:
(a) forming a titanium nitride (TiN) layer on a substrate in a first process chamber;
(b) removing reaction by-products generated during titanium nitride (TiN) layer formation from the first process chamber;
(c) treating the titanium nitride (TiN) layer with a hydrogen-containing plasma;
(d) moving the substrate with the titanium nitride (TiN) layer thereon into a second process chamber different from the first process chamber; and
(e) exposing the titanium nitride (TiN) layer to a silicon-containing gas to convert the titanium nitride (TiN) layer to a titanium silicide nitride (TiSiN) layer.

52. The method of claim 51 wherein the reaction by-products are removed from the first process chamber in step (b) by providing a purge gas thereto and evacuating both the purge gas and the reaction by-products therefrom.

53. The method of claim 52 wherein the purge gas comprises one or more gases selected from the group consisting of nitrogen (N₂), hydrogen (H₂), helium (He), argon (Ar), neon (Ne) and xenon (Xe).

54. The method of claim 52 wherein the purge gas is provided to the process first chamber for up to about 5 minutes.

55. The method of claim 51 wherein the titanium nitride (TiN) layer is formed from a reaction of titanium tetrachloride (TiCl₄) and ammonia (NH₃).

56. The method of claim 51 wherein the silicon-containing gas is selected from the group consisting of silane (SiH₄) and disilane (Si₂H₆).

57. The method of claim 56 wherein the silicon-containing gas is mixed with one or more gases selected from the group consisting of hydrogen (H₂), nitrogen (N₂), argon (Ar) and helium (He).

58. The method of claim 57 wherein the silicon-containing gas is mixed with hydrogen (H₂).

59. The method of claim 58 wherein the ratio of the silicon-containing gas to the hydrogen (H₂) is greater than 1.

60. The method of claim 51 wherein the hydrogen-containing plasma is generated by applying an electric field to a gas mixture comprising one or more gases selected from the group consisting of hydrogen (H₂), ammonia (NH₃), hydrazine (N₂H₄), nitrogen (N₂), argon (Ar) and helium (He).

61. The method of claim 51 wherein the titanium nitride (TiN) layer is treated with the hydrogen-containing plasma for about 5 seconds to about 100 seconds.

62. A method of forming a barrier layer for use in integrated circuit fabrication, comprising:
forming a titanium nitride (TiN) layer on a substrate in a first process chamber;
moving the substrate with the titanium nitride (TiN) layer thereon into a second process chamber different from the first process chamber;
exposing the titanium nitride (TiN) layer to a silicon-containing gas to convert the titanium nitride (TiN) layer to a titanium silicide nitride (TiSiN) layer; and
forming a metal layer on the titanium silicide nitride (TiSiN) layer.

63. The method of claim 62 wherein the titanium nitride (TiN) layer is formed from a reaction of titanium tetrachloride (TiCl₄) and ammonia (NH₃).

64. The method of claim 62 wherein the silicon-containing gas is selected from the group consisting of silane (SiH₄) and disilane (Si₂H₆).

65. The method of claim 64 wherein the silicon-containing gas is mixed with one or more gases selected from the group consisting of hydrogen (H₂), nitrogen (N₂), argon (Ar) and helium (He).

66. The method of claim 65 wherein the silicon-containing gas is mixed with hydrogen (H₂).

67. The method of claim 66 wherein the ratio of the silicon-containing gas to the hydrogen (H₂) is greater than 1.

68. The method of claim 62 further comprising treating the titanium nitride (TiN) layer with a hydrogen-containing plasma prior to exposing the titanium nitride (TiN) layer to the silicon-containing gas.

69. The method of claim 68 wherein the titanium nitride (TiN) layer is treated after the substrate with the titanium nitride (TiN) layer thereon is moved into the second process chamber.

70. The method of claim 68 wherein the titanium nitride (TiN) layer is treated before the substrate with the titanium nitride (TiN) layer thereon is moved into the second process chamber.

72. The method of claim 68 wherein the hydrogen-containing plasma is generated by applying an electric field to a gas mixture comprising one or more gases selected from the group consisting of hydrogen (H₂), ammonia (NH₃), hydrazine (N₂H₄), nitrogen (N₂), argon (Ar) and helium (He).

73. The method of claim 68 wherein the titanium nitride (TiN) layer is treated with the hydrogen-containing plasma for about 5 seconds to about 100 seconds.
